(19) United States
(12) Patent Application Publication
(10) Pub. No.: US 2002/0108778 A1
(43) Pub. Date: Aug. 15, 2002

(54) Apparatus for shielding transmission line effects on a printed circuit board

(75) Inventors: Terrance J. Dishongh, Hillsboro, OR (US); James D. Jackson, Beaverton, OR (US)

Correspondence Address: Schwegman, Lundberg, Woessner & Kluth, P.A., P. O. Box 2938, Minneapolis, MN, 55402, US

(73) Assignee: Intel Corporation

(21) Appl. No.: 09/732,115

(22) Filed: Dec. 7, 2000

(51) Int. Cl. H05K 7/06; H05K 9/00

(52) U.S. Cl. 174/261; 174/262; 361/777

(57) ABSTRACT

A printed circuit board (PCB) includes metallization portions that are enshrouded with a carbon-based cladding. The carbon-based cladding reduces noise coupling between, for example, signal lines within the metallization pattern. In addition, in at least one embodiment, the carbon-based cladding is used to implement one or more electrical resistors (e.g., pull-up and/or pull-down resistors) within the PCB. The carbon-based cladding can also be used to decrease the propagation delay of the signal lines of the PCB.

### FIELD OF THE INVENTION

The invention relates generally to printed circuit boards and, more particularly, to techniques for implementing transmission structures on printed circuit boards.

### BACKGROUND OF THE INVENTION

Cross talk between signal lines on a printed circuit board (PCB) is a significant problem impacting the performance of computers and other electronic devices. Typically, the level of cross talk between two lines is directly related to the lateral distance between the lines. That is, the cross talk between two signal lines will normally increase as the distance between the two signal lines decreases. Cross-talk levels are also related to the signal frequencies being carried by the signal lines, with higher signal frequencies typically resulting in greater coupling between the lines. Therefore, as electronic components become smaller and greater functionality is packed within existing form factors, the level of cross talk between signal lines within PCB circuits will tend to increase. Similarly, as the operational speeds of circuits increase, cross-talk levels will also tend to increase. For these reasons, techniques for effectively dealing with cross talk are becoming increasingly important.

### BRIEF DESCRIPTION OF THE DRAWINGS

FIGS. 1 and 2 are a top view and a sectional side-view, respectively, illustrating a printed circuit board (PCB) in accordance with one embodiment of the present invention;

FIGS. 3-8 are diagrams illustrating various stages of a process for manufacturing a PCB in accordance with one embodiment of the present invention; and

FIG. 9 is a sectional side view illustrating a multi-layer PCB utilizing carbon-based cladding to implement a pull-down resistor in accordance with one embodiment of the present invention.

### DETAILED DESCRIPTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein in connection with one embodiment may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

The present invention relates to techniques and structures that can be used to reduce noise coupling between signal lines (and other conductor structures) on a printed circuit board (PCB). One or more conductor elements within a PCB are coated with a carbon-based cladding material that modifies an electromagnetic field pattern about the element in a manner that reduces radiative coupling between the element and neighboring conductor structures within the PCB. In at least one embodiment, the carbon-based cladding material is also used to provide one or more finite electrical resistances within the PCB. In some implementations, the carbon-based cladding will provide a significant reduction in propagation delay on the signal lines of the PCB, thus allowing enhanced signal transmission speeds within circuits using the PCB. The techniques and structures can be beneficially implemented in any electrical system utilizing a circuit board that suffers from cross-talk related performance degradation. The techniques and structures are particularly beneficial for use in applications where reduced component size is desirable such as, for example, computer motherboards, server boards, cartridge products, and circuit boards within mobile systems.

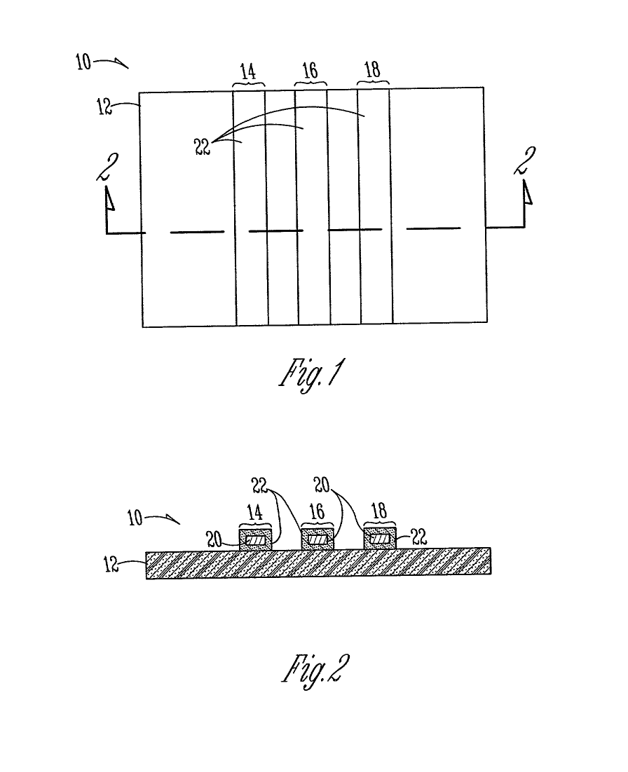

FIGS. 1 and 2 are a top view and a sectional side-view, respectively, illustrating a PCB 10 in accordance with one embodiment of the present invention. In a typical application, the PCB 10 will be used to provide circuit interconnections between the terminals of one or more electrical components mounted on the PCB 10. As shown, the PCB 10 includes a dielectric board member 12 having a number of signal lines 14, 16, 18 situated on an upper surface thereof Eachofthe signal lines 14, 16, 18 includes an elongated conductor element 20 that is surrounded by a carbon-based cladding 22 (indicated by shading in the figures). The conductor elements 20 of the signal lines 14, 16, 18 are each operative for carrying an electrical signal during normal circuit operation. As described above, the carbon-based cladding 22 is operative for reducing noise coupling between the signal carrying conductor elements 20 of the signal lines 14, 16, 18. It should be appreciated that the PCB 10 of FIGS. 1 and 2 has been made relatively simple for ease of illustration and to facilitate understanding of the inventive principles. In practice, a PCB will typically include a much larger and more complex array of conductive elements.

In conceiving the present invention, it was determined that carbon-based cladding could be used to modify the electromagnetic field structure about a signal conductor on a PCB in such a way that coupling between the signal conductor and nearby structures is reduced. That is, the carbon-based cladding attenuates the field components about the signal conductor to reduce interaction between the field components and surrounding signal structures. Thus, by utilizing the carbon-based cladding, the signal lines on a PCB can be spaced more closely together than they could be without the cladding, allowing greater circuit densities to be achieved. Alternatively, with the inter-line spacing being the same, the carbon-based cladding 22 can be used to transmit higher frequencies on the signal lines than would be possible with unclad lines. In many cases, the carbon-based cladding can be added without changing the PCB circuit geometry, which is desirable when working with through-hole mount components.

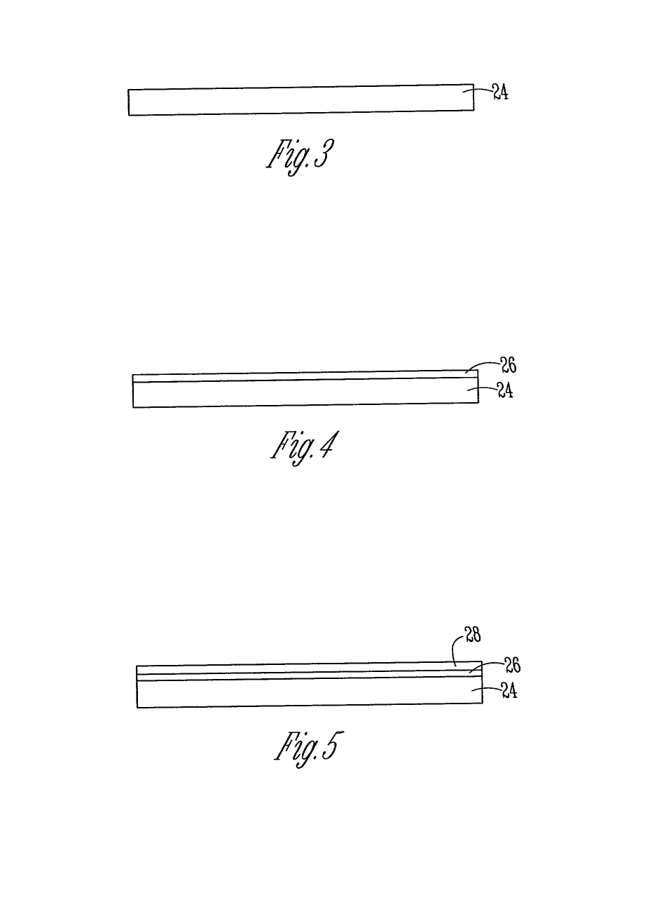

FIGS. 3-8 are diagrams illustrating various stages of a process for manufacturing a PCB in accordance with one embodiment of the present invention. As illustrated in FIG. 3, the process starts with a bare dielectric board member 24. The board member 24 can consist of any type of dielectric board material to which a carbon-based cladding material can be adhered. Typically, a board material will be selected based upon the dielectric and structural properties needed for a particular circuit application. In one embodiment, for example, an epoxy-based board material is used (either with or without glass reinforcement). Other possible board materials include carbon derivatives, long chain polymers, and others.

The upper surface of the dielectric board member 24 is first prepared using a chemical etch process. As shown in FIG. 4, a layer of carbon-based cladding 26 is then deposited onto the upper surface of the dielectric board member 24. The carbon-based cladding 26 consists of a material having a high carbon concentration (preferably higher than 60% by weight) that can be evenly deposited onto the surface of the board member 24. In one embodiment, the carbon-based cladding consists of almost pure carbon. The carbon-based cladding 26 can be applied using any of a number of different processes including vapor deposition, sputtering, carbon bath, spraying, and others.

In one approach, a well known BlackHole® carbon deposition process (developed by MacDermid Corporation) is used to apply the cladding. The BlackHole® process is typically used in the PCB industry to apply a carbon-based material to the inner surface of a through-hole in a circuit board to improve the adhesion of a metallic plating to the inner surface of the hole when creating a plated through-hole in the board. After the plating has been applied to the through-hole, the carbon based material is typically washed out before further PCB processing is performed. In accordance with at least one embodiment of the present invention, the BlackHole® process is used to apply a cladding layer that is not removed from the circuit board assembly during the manufacturing process. That is, the carbon-based material applied using the BlackHole® process remains as an integral and functional part of the manufactured PCB. Using the BlackHole® process, a carbon black material is applied to the surface of the dielectric board member 24 using a carbon black dispersion technique. The carbon black material is a relatively pure form of carbon that typically exceeds 99% carbon by weight. Because the BlackHole® process is already an established process in many manufacturing facilities, the inventive principles can often be implemented with little or no cost impact on the manufactured PCB.

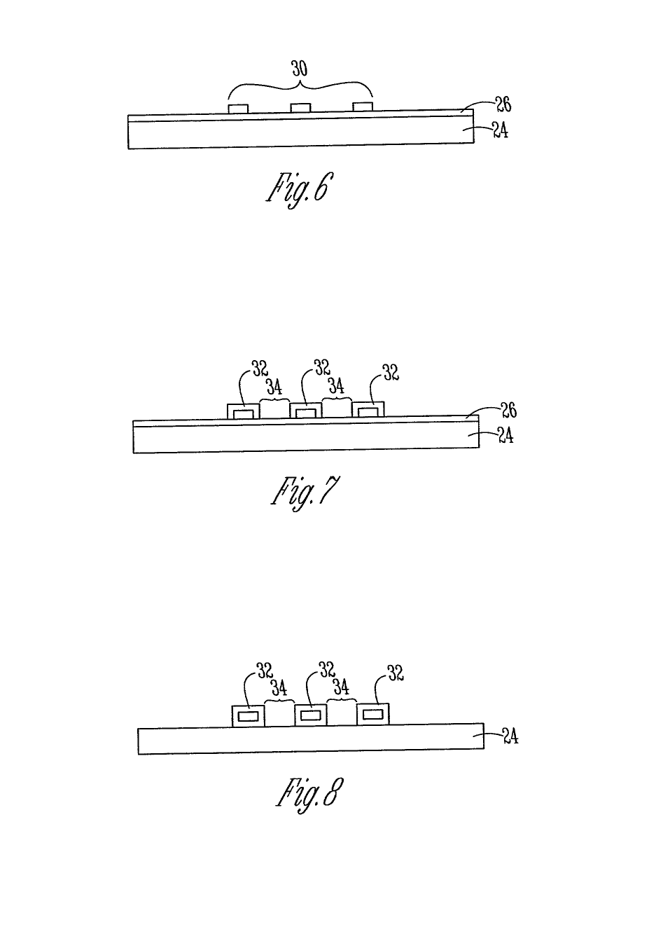

After the carbon-based cladding 26 has been applied to the dielectric board member 24, the cladding is chemically cleaned using, for example, an acid wash. As illustrated in FIG. 5, a metallic layer 28 is then applied to the upper surface of the carbon-based cladding 26. The metal or alloy that is used for the metallic layer 28 will preferably be one that adheres well to the carbon-based cladding 26 (e.g., copper, aluminum, etc.). With reference to FIG. 6, after the metallic layer 28 has been applied, the layer 28 is further processed to form a metallization pattern 30 on the upper surface of the cladding 26. The metallization pattern 30 can include, for example, signal line traces, ground pads, terminal pads, matching structures, and/or any other conductive structure commonly found on a circuit board. Any of a number of different techniques can be used to fashion the metallization pattern 30 including, for example, photolithography techniques, laser ablation techniques, and others.

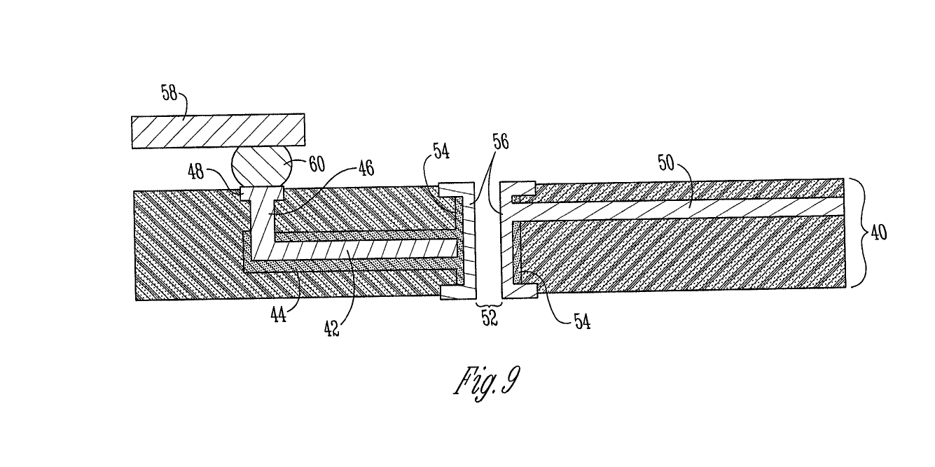

After the metallization pattern 30 has been formed, the resulting metallic structures (e.g., signal lines, contact pads, etc.) are cleaned and another layer of carbon-based cladding 32 is applied to the top and side portions of the structures, as shown in FIG. 7. Typically, the same carbon deposition process will be used to apply this cladding layer that was used previously to cover the dielectric board member 24. After the second layer of cladding 32 has been applied, further processing and shaping of the carbon-based cladding material may be undertaken. In one embodiment, as shown in FIG. 8, all cladding material is removed from the regions 34 between adjacent signal lines to increase the impedance between the signal lines. Other portions of the cladding material may also be removed at this point. The cladding material can be removed using any of a plurality of different methods including, for example, photolithography techniques. In one approach, a photolithography mask is used that is patterned to cover the sidewalls of the conductive structures with photoresist to ensure that the cladding on the side portions of the signal lines remains in tact during the subsequent etch phase. In an alternative embodiment, the carbon-based cladding material is not removed from the regions 34 between adjacent signal lines. By leaving the inter-signal cladding in tact, a lower impedance is achieved between the signal lines. Typically, the decision on whether to remove or maintain the inter-signal cladding will be made during the PCB design phase based on the desired characteristic impedance and inter-line spacing of the signal lines of the PCB. The thickness of the inter-signal cladding layer may also be used as a tuning mechanism to tune the impedance of the lines during the manufacturing process.

After the carbon-based cladding 26, 34 associated with the dielectric board member 24 has been appropriately fashioned, one or more additional board layers may be added to the PCB structure. The additional layers can include normal PCB layers or cladding-modified layers as described above. In one approach, via connections and/or plated through-holes are used to provide signal communication between the layers. One or more additional photolithography steps may also be performed on the upper board layer to expose portions of the metallization thereon to act as standard surface mount pads. The deposition of the carbon-based cladding and the metal layers on the PCB may be done in either an additive or a subtractive process.

To achieve enhanced de-coupling between adjacent signal lines on a PCB, the carbon-based cladding should surround the signal line conductors on all sides thereof (including the top, bottom, and both sides) in the region where coupling is likely. Less than total coverage of the relevant conductor structures (e.g., covering only side and top portions of the structures) will typically result in greater coupling between the lines, but may also simplify the fabrication process (by, for example, eliminating the initial carbon deposition step). Therefore, a coverage tradeoffwill typically be made during the design process based on the needs of the particular application. In one embodiment of the invention, carbon-based cladding is limited to portions of the metallization pattern that may present coupling problems during subsequent operation of a circuit including the PCB. For example, in one approach, cladding is only used on portions of the signal lines that are sufficiently close to other signal lines to couple energy thereto at the anticipated frequency of operation. The carbon-based cladding can be selectively applied to the relevant portions of the metallization pattern (using, for example, masking techniques) or an entire layer of cladding can be applied and selected portions subsequently removed. In another embodiment, most or all of the metallization pattern on the surface of a dielectric board is covered with the carbon-based cladding. The signal lines of the PCB that are carbon clad in accordance with the invention can include any type of transmission structure that can be implemented on a circuit board including, for example, microstrip transmission lines, strip line transmission lines, co-planar waveguide, and others.

In conceiving the present invention, it was found that the carbon-based cladding used to reduce noise coupling in a PCB could also be used to perform other functions within the corresponding circuitry. As is well known, carbon-based materials typically have a conductivity somewhere between that of metals (and other known conductors) and dielectric materials. Thus, carbon-based materials (including pure carbon) are commonly used in the electronics industry to fashion discrete resistor components for insertion into electrical circuits. In one aspect of the present invention, the carbon-based cladding surrounding various conductor structures within a PCB is used to implement one or more electrical resistances within the PCB. In one approach, for example, the carbon-based cladding is used to form one or more pull-up or pull-down resistors within a circuit.

FIG. 9 is a sectional side view of a multi-layer PCB 40 that utilizes carbon-based cladding to implement a pull-down resistor in accordance with one embodiment of the present invention. As shown, a signal line conductor 42 on a central layer of the PCB 40 is covered with a carbon-based cladding 44 as described previously. A via connection 46 extends through the upper layers of the PCB 40 to conductively couple a contact pad 48 on the upper surface of the PCB 40 to the signal line conductor 42. A ground plane 50 is located on another layer of the PCB 40 and a plated through-hole 52 extends through the various layers of the PCB 40. The plated through-hole 52 includes a layer of carbon-based cladding 54 covering an inner surface of the corresponding through-hole and a metallic plating 56 covering the cladding 54. The ground plane 50 is directly connected to the metallic plating 56 of the plated through-hole 52. The signal line conductor 42, however, is not directly connected to the metallic plating 56. Instead, the signal line conductor 42 is conductively coupled to the metallic plating 56 through aportion of the carbon-based cladding 54 (and also possibly a portion of the cladding 44 about the signal line conductor 42) which acts as a series resistance.

A terminal 58 of a ball grid array (BGA) package is conductively coupled to the contact pad 48 via solder ball 60. The terminal 58 is therefore conductively coupled to the ground plane 50 through the series resistance associated with the carbon-based cladding. The series resistance may thus be used as a pull-down resistor for the circuit within the BGA package. A similar approach can be used to implement a pull-up resistor for the circuit. The magnitude of the series resistance typically be governed by the dimensions (e.g., thickness and length) of the cladding material in the region of interest as well as the electrical conductivity of the cladding material. As is well known, the bulk conductivity of the cladding material will typically depend upon the concentration of carbon within the material as well as the other constituents of the material.

As will be apparent to a person of ordinary skill in the art, many other resistor arrangements also exist in accordance with the present invention. For example, in an alternative approach to the PCB structure of FIG. 9, the plated through-hole 52 is not lined with a carbon-based cladding 54. Instead, the carbon-based cladding 44 of the signal line conductor 42 is used to form the series resistance between the line 42 and the metallic plating 56. In another embodiment, a series electrical resistance is formed between two signal lines on a common board surface using a carbon-based cladding surrounding one or both of the signal lines.

In at least one embodiment of the present invention, the carbon-based cladding that is applied to the signal conductors of the PCB is designed to decrease the propagation delay of the signal lines of the PCB. This decrease in propagation delay will typically allow higher frequency signaling to be used on the signal lines resulting in significant PCB performance gains. As is well known, the propagation delay of a signal line is related to the characteristic impedance of the line. For a microstrip line, for example, the propagation delay is directly proportional to the square root of the characteristic impedance of the line. The characteristic impedance of a microstrip line having a uniform dielectric board layer can be calculated using the following equation:

$${Z}_{0} = [ \frac{87}{\sqrt{{ϵ}_{r} + 1.41}} ] \cdot ln [ \frac{5.98 h}{0.8 w + t} ]$$

where εᵣ is the dielectric constant of the board material, h is the thickness of the board material, w is the line width of the signal conductor, and t is the thickness of the signal conductor. Therefore, if a carbon-based cladding material having a dielectric constant that is greater than that of the dielectric board material forms a portion of the dielectric layer, then the characteristic impedance (Z₀) of the microstrip line will be reduced, thus reducing the propagation delay of the line. With proper design, increases in signal speed of up to 25% or more are believed possible using the inventive techniques.

Although the present invention has been described in conjunction with certain embodiments, it is to be understood that modifications and variations may be resorted to without departing from the spirit and scope of the invention as those skilled in the art readily understand. Such modifications and variations are considered to be within the purview and scope of the invention and the appended claims.

What is claimed is:

1. A printed circuit board (PCB) comprising:
a dielectric board member; and
a first signal line supported on said dielectric board member, said first signal line including an elongated conductive member that is enshrouded with a carbon-based cladding over at least a portion of its length.

2. The PCB of claim 1, comprising:
a second signal line supported on said dielectric board member, said second signal line including a second elongated conductive member that is enshrouded with a carbon-based cladding over at least a portion of its length, said second signal line being adjacent to said first signal line.

3. The PCB of claim 2, wherein:
said carbon-based cladding of said second signal line is continuous with said carbon-based cladding of said first signal line.

4. The PCB of claim 2, wherein:
said carbon-based cladding of said second signal line is discontinuous with said carbon-based cladding of said first signal line.

5. The PCB of claim 1, comprising:
a second dielectric board member disposed above said first dielectric board member and said first signal line.

6. The PCB of claim 1, wherein:
said elongated conductive member is fully covered over top, bottom and side portions thereof with said carbon-based cladding for said at least a portion of its length.

7. The PCB of claim 1, wherein:
said elongated conductive member is covered with said carbon-based cladding over greater than 90% of an outer surface thereof.

8. The PCB of claim 1, wherein:
said carbon based cladding has a dielectric constant that is greater than a dielectric constant associated with said dielectric board member.

9. A printed circuit board (PCB) comprising:
a first metallic member that is covered over at least a portion thereof with a carbon-based cladding, said first metallic member to form a first node within an electrical circuit; and
a second metallic member proximate to said first metallic member, said second metallic member to form a second node within the electrical circuit;
wherein a portion of said carbon-based cladding provides a finite electrical resistance between said first metallic member and said second metallic member, said finite electrical resistance to allow an electrical current to flow between said first and second nodes of the electrical circuit during circuit operation.

10. The PCB of claim 9 wherein:
said second metallic member physically contacts said carbon-based cladding of said first metallic member.

11. The PCB of claim 9 wherein:
said second metallic member is also covered over at least a portion thereof with a carbon-based cladding, wherein said carbon-based cladding of said second metallic member physically contacts said carbon-based cladding of said first metallic member.

12. The PCB of claim 9 wherein:
said first metallic member includes an elongated signal line conductor.

13. The PCB of claim 9 wherein:
said first metallic member includes metallic plating within a plated through-hole.

14. The PCB of claim 9 wherein:
said first and second metallic members each include an elongated signal line conductor.

15. A multi-layer printed circuit board (PCB) comprising:
a first dielectric board member having a signal line supported thereon;
a second dielectric board member having a conductive terminal member supported thereon; and
a plated through-hole extending through said first and second dielectric board members, said plated through-hole including a metallic plating covering a carbon-based cladding adhered to an inner surface of said through-hole;
wherein said signal line is conductively coupled to said metallic plating of said plated through-hole through a portion of said carbon-based cladding, said portion of said carbon-based cladding to provide a finite electrical resistance between said signal line and said conductive terminal member within an electrical circuit to be formed using said multi-layer PCB.

16. The multi-layer PCB claimed in claim 15, wherein:
said signal line includes an elongated conductive member that is enshrouded with a carbon-based cladding over at least a portion of its length.

17. The multi-layer PCB claimed in clain 15, wherein:
said conductive terminal member forms a ground terminal on said second dielectric board member, said finite electrical resistance to act as a pull-down resistance within said electrical circuit.

18. The multi-layer PCB claimed in claim 15, wherein:
said conductive terminal member forms a supply terminal on said second dielectric board member, said finite electrical resistance to act as a pull-up resistance within said electrical circuit.

19. An electrical subsystem comprising:
a printed circuit board (PCB) including at least one dielectric board member having a plurality of conductive interconnects for providing circuit interconnections within said electrical subsystem, said plurality of conductive interconnects including at least one interconnect that is enshrouded with a carbon-based cladding over at least a portion thereof; and
a plurality of external electrical components coupled to said plurality of conductive interconnects of said PCB to form an electrical circuit.

20. The electrical subsystem of claim 19, wherein:
said electrical subsystem is a computer processor board and said plurality of electrical components includes at least one digital processing device.

21. The electrical subsystem of claim 19, wherein:
said at least one interconnect is adjacent to another interconnect on said at least one dielectric board member, said carbon-based cladding to reduce noise coupling between said at least one interconnect and said another interconnect.

22. The electrical subsystem of claim 19, wherein:
said at least one interconnect is covered with said carbon-based cladding over top, bottom, and side portions thereof.

23. The electrical subsystem of claim 19, wherein:
a portion of said carbon-based cladding provides a finite electrical resistance between two conductive interconnects of said PCB, said finite electrical resistance to be used as a circuit element within said electrical circuit.

24. A method for manufacturing a printed circuit board (PCB) comprising:
providing a dielectric board member;
depositing a carbon-based cladding on an upper surface of said dielectric board member;
adding a metallic layer to an upper surface of said carbon-based cladding;
processing said metallic layer to produce a predetermined metallization pattern on said carbon-based cladding; and
depositing additional carbon-based cladding over at least a portion of said predetermined metallization pattern.

25. The method claimed in claim 24, comprising:
removing carbon-based cladding from aregion between two signal lines of said predetermined metallization pattern to expose a portion of said upper surface of said dielectric board member.

26. The method claimed in claim 24, comprising:
providing a second dielectric board member; and
placing said second dielectric board member over said additional carbon-based cladding.

27. The method claimed in claim 24, wherein:
depositing a carbon-based cladding includes applying a carbon black material to said upper surface of said dielectric board member.

28. The method claimed in claim 24, wherein:
said dielectric board member includes a glass-reinforced epoxy material.

29. The method claimed in claim 24, wherein:
processing said metallic layer includes using photolithography techniques.
